(19) United States
(12) Patent Application Publication
(10) Pub. No.: US 2016/0293459 A1
(43) Pub. Date: Oct. 6, 2016

(54) APPARATUS FOR PROCESSING SUSTRATE AND SEMICONDUCTOR FABRICATION LINE INCLUDING THE SAME

(71) Applicant: Samsung Electronics Co., Ltd., Suwon-si (KR)

(72) Inventors: Sangyeob Cha, Seoul (KR); Yongduk Park, Hwaseong-si (KR); Young-Chun Jang, Hwaseong-si (KR)

(21) Appl. No.: 15/082,474

(22) Filed: Mar. 28, 2016

(30) Foreign Application Priority Data
Apr. 3, 2015 (KR) 1020150047578

(51) Int. Cl. H01L 21/67

(52) U.S. Cl. CPC H01L 21/67196; H01L 21/67167; H01L 21/67201; H01L 21/67184; H01L 21/67207

(57) ABSTRACT

In a substrate processing apparatus and a fabrication line including the same, the substrate processing apparatus includes a first unit apparatus performing a first unit process of a substrate, a second unit apparatus facing the first unit apparatus and performing a second unit process, and a load port providing a carrier receiving the substrate to the first unit apparatus and the second unit apparatus. The load port connects between the first unit apparatus and the second unit apparatus.

### CROSS-REFERENCE TO RELATED APPLICATION

This application claims priority under 35 U.S.C. §119 to Korean Patent Application No. 10-2015-0047578 filed Apr. 3, 2015, in the Korean Intellectual Property Office, the entire contents of which are hereby incorporated by reference.

### BACKGROUND

The inventive concepts relate to a system for processing a substrate, and more particularly, to an apparatus for processing a substrate, and a fabrication line including the same.

A semiconductor device may be manufactured by a plurality of unit processes. The unit processes may include a thin film deposition process, a diffusion process, a heat treatment process, a photolithography process, a polishing process, an etching process, an ion implantation process, and a cleaning process. An apparatus for processing a substrate may perform the unit processes independently. The apparatus for processing a substrate may be installed in a clean room. The size of the apparatus for processing a substrate has a tendency to increase to correspond to the appearance of a large-area substrate. Nevertheless, an area increase of the apparatus may cause a decrease in productivity. Therefore, research and development for the apparatus for processing a substrate with space efficiency have been performed.

### SUMMARY

An example embodiment of the inventive concepts may provide an apparatus for processing a substrate and a fabrication line including the same, capable of improving space efficiency.

According to example embodiment of the inventive concepts, an apparatus for processing a substrate may include a first unit apparatus performing a first unit process for a substrate, a second unit apparatus facing the first unit apparatus and performing a second unit process, and a load port providing a carrier receiving the substrate to the first unit apparatus and the second unit apparatus. The load port may connect between the first unit apparatus and second unit apparatus and may be disposed between the first unit apparatus and the second unit process.

In some embodiments, the load port may comprise a first gate wall connected to the first unit apparatus, a second gate wall connected to the second unit apparatus, and a table connecting between the first gate wall and the second gate wall.

In some embodiments, the load port may further comprise a stage disposed on the table. The stage may transfer the carrier to the first gate wall and the second gate wall.

In some embodiments, the first and second gate walls may comprise first and second doors, respectively. When the stage is moved to the first and second gate walls, one of the first and second doors may be opened and the other is closed.

In some embodiments, the stage may rotate an entrance of the carrier from a direction toward one of the first and second gate walls to a direction toward the other.

In some embodiments, the stage may rotate the carrier by 180°.

In some embodiments, the stage may rotate at a center of the table.

In some embodiments, the first unit apparatus may further comprise a first EFEM coupled to the first gate wall, a first load lock chamber connected to the first EFEM, a first transfer chamber connected to the first load lock chamber, and first process chambers connected to the first transfer chamber in a cluster type. The second unit apparatus may further comprise a second EFEM coupled to the second gate wall, a second load lock chamber connected to the second EFEM, a second transfer chamber connected to the second load lock chamber, and second process chambers connected to the second transfer chamber in a cluster type.

In some embodiments, the first and second process chambers may comprise an etching apparatus and a thin film deposition apparatus, respectively.

According to example embodiment of the inventive concepts, a fabrication line may include a clean room and an apparatus for processing a substrate provided in the clean room and performing a substrate manufacturing process. The apparatus for processing the substrate may include a first unit apparatus performing a first unit process for the substrate, a second unit apparatus facing the first unit apparatus and performing the second unit process for the substrate, and a load port providing a carrier receiving the substrate to the first unit apparatus and the second unit apparatus. The load port may connect between the first unit apparatus and second unit apparatus and may be disposed between the first unit apparatus and the second unit process.

In some embodiments, the clean room may comprise service regions in which the first unit apparatus and the second unit apparatus are disposed, and an operating region in which the load port is disposed between the service regions. A width of the operating region may be less than a distance between the first unit apparatus and the second unit apparatus within each of the service regions.

In some embodiments, the width of each of the operating regions may be substantially equal to a width of the load port.

In some embodiments, the load port may comprise a first gate wall connected to the first unit apparatus, a second gate wall connected to the second unit apparatus, a table connecting between the first and second gate walls, and a stage disposed on the table. The stage may transfer the carrier between the first and second gate walls.

In some embodiments, the stage may rotate an entrance of the carrier from a direction of the first gate wall to a direction of the second gate wall.

In some embodiments, the fabrication line may further comprise a transfer apparatus disposed in the clean room. The transfer apparatus may provide the carrier on the stage.

According to example embodiment of the inventive concepts, a method for processing a substrate may include providing a carrier receiving a substrate to a load port, providing the substrate form the carrier to a first unit apparatus to perform a first unit process for the substrate, putting the substrate in a carrier after performing the first unit process, rotating the carrier on the load port from a direction of the first unit apparatus to a direction of a second unit apparatus facing the first unit apparatus, and providing the substrate from the carrier to the second unit apparatus to perform a second unit process for the substrate.

In some embodiments, the first and second unit processes may be an etching process and a thin film deposition process, respectively.

In some embodiments, the load port may comprise a first gate wall connected to the first unit apparatus, a second gate wall connected to the second unit apparatus, a table connecting between the first gate wall and the second gate wall, and a stage disposed on the table to support the carrier. Rotating of the carrier may comprise rotating an entrance of the carrier from a direction of the first gate wall to a direction of the second gate wall.

In some embodiments, providing the substrate to the first unit apparatus may comprise transferring the carrier from a center of the table to the first gate wall, and opening a cover of the carrier and a first door of the first gate wall.

In some embodiments, the carrier may be rotated on a center of the table by the stage. Providing the substrate to the second unit apparatus may comprise transferring the carrier from the center of the table to the second gate wall, and opening a cover of the carrier and a second door of the second gate wall.

### BRIEF DESCRIPTION OF THE FIGURES

The foregoing and other features and advantages of the inventive concepts will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 illustrates a plan view of a substrate for explaining a substrate processing apparatus according to the inventive concepts;

FIG. 2 illustrates a typical fabrication line for processing the substrate of FIG. 1;

FIG. 3 is a plan view illustrating a fabrication line according to an embodiment of the inventive concept;

FIG. 4 is a plan view illustrating a substrate processing apparatus of FIG. 3;

FIG. 5 is a perspective view illustrating a carrier of FIG. 4;

FIGS. 6 and 7 are plan and front views illustrating an example of a substrate processing apparatus of FIG. 4, respectively;

FIGS. 8 and 9 are plan and cross sectional views illustrating an example of a substrate processing apparatus of FIG. 4, respectively;

FIGS. 10 and 11 are perspective and cross sectional views illustrating first and second EFEMs and a load port of FIG. 7, respectively;

FIG. 12 is a diagram illustrating a host computer for controlling a fabrication line of FIG. 3;

FIG. 13 is a flow chart illustrating a method for processing a substrate by a control of a host computer of FIG. 12;

FIGS. 14 to 16 illustrate an operation of a load port in the step of FIG. 13 in which the substrate is provided to a first unit apparatus;

FIG. 17 illustrates a carrier which is rotated in a direction of a second EFEM of FIG. 11; and

FIGS. 18 to 20 illustrate an operation of a load port in the step of FIG. 13 in which the substrate is provided to a second unit apparatus.

### DETAILED DESCRIPTION

Embodiments will be described in detail with reference to the accompanying drawings. The inventive concepts, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concepts. Unless otherwise noted, like reference numerals denote like elements throughout the attached drawings and written description, and thus descriptions will not be repeated. In the drawings, the sizes and relative sizes of layers and regions may be exaggerated for clarity.

As used herein, a term may be intended to illustrate embodiments of the inventive concept and may be not intended to limit the inventive concepts. In this specification, a singular may include plural unless specifically states otherwise in a text or figures. In addition, terms such as a substrate, a unit apparatus, a load port, a stage, a carrier, a transfer apparatus, a robot, and a region in the specification may be understood in terms of a general semiconductor and device.

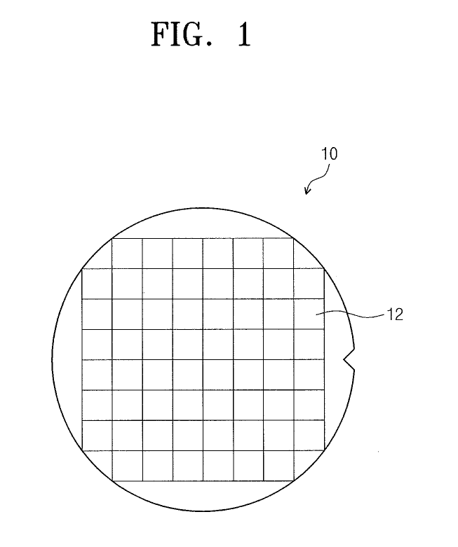

FIG. 1 illustrates a substrate 10 for explaining a substrate processing apparatus according to the inventive concepts.

Referring to FIG. 1, the substrate 10 may include a semiconductor substrate. Alternatively, the substrate 10 may include a glass substrate or a plastic substrate. The substrate 10 may include a plurality of unit devices 12. Each of the unit devices 12 may be formed through a plurality of unit processes. For example, the unit devices 12 may include a memory device, a central processing unit (CPU), a light sensor, or a power device.

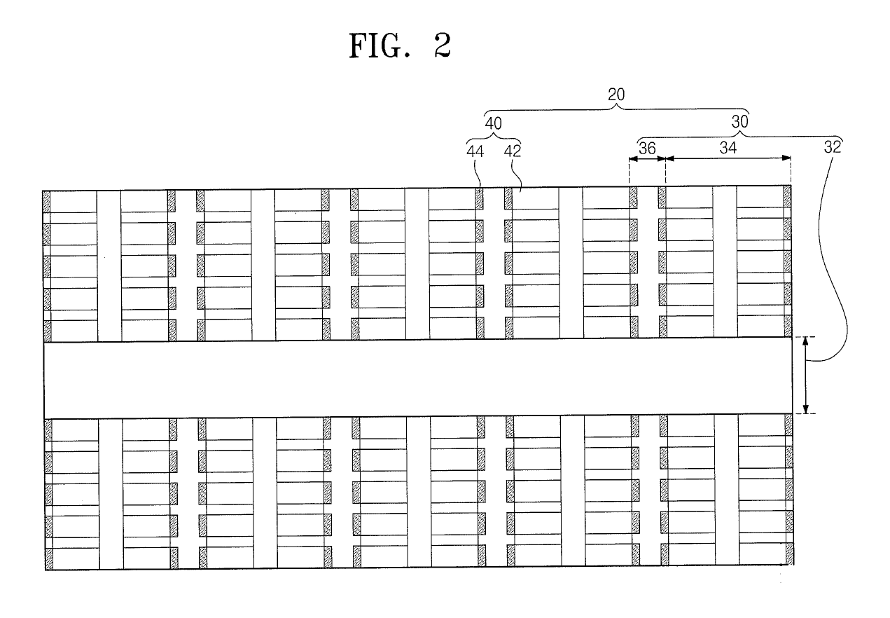

FIG. 2 illustrates a conventional fabrication line 20 for processing the substrate 10 of FIG. 1.

Referring to FIGS. 1 and 2, the fabrication line 20 may be a semiconductor plant or a semiconductor fabrication line. For example, the fabrication line 20 may include a clean room 30 and a substrate processing apparatuses 40.

The clean room 30 may be defined as a space or region where most of particles in an air are removed. The substrate processing apparatuses 40 may be installed in the clean room 30. The substrate processing apparatuses 40 may be disposed to correspond to unit processes for the substrate 10, respectively.

The substrate processing apparatuses 40 may include unit apparatuses 42 and load ports 44. The unit apparatuses 42 may perform a manufacturing process for the substrate 10. The load ports 44 may supply the substrate 10 to the unit apparatuses 42. The load ports 44 and the unit apparatuses 42 may be connected in a one-to-one manner. The unit apparatuses 42 may be disposed adjacent to each other. In addition, the load ports 44 may be disposed adjacent to each other.

The clean room 30 may include a main passage 32, a service region 34, and an operating region 36. The main passage 32 may be a main movement path of an operator and materials (or parts). The service region 34 may be a region in which the unit apparatuses 42 are installed. Alternatively, the service region 34 may be a region which is provided between the unit apparatuses without the load ports 44. The operating region 36 may be a region in which the load ports 44 are installed. Alternatively, the operating region 36 may be a region which is provided between the load ports 44 without the unit apparatuses 42

An area of the service region 34 and the operating region 36 may be increased in proportion to a size of the substrate 10. For example, the substrate 10 may have a tendency to be enlarged from 4 inches to 12 inches (300 mm). The enlarged substrate 10 may have a high productivity. However, the size and an occupying area of the substrate processing apparatuses 40 may be increased. The number of the substrate processing apparatuses 40 to be installed in the clean room 30 may be reduced and thereby the productivity may be decreased.

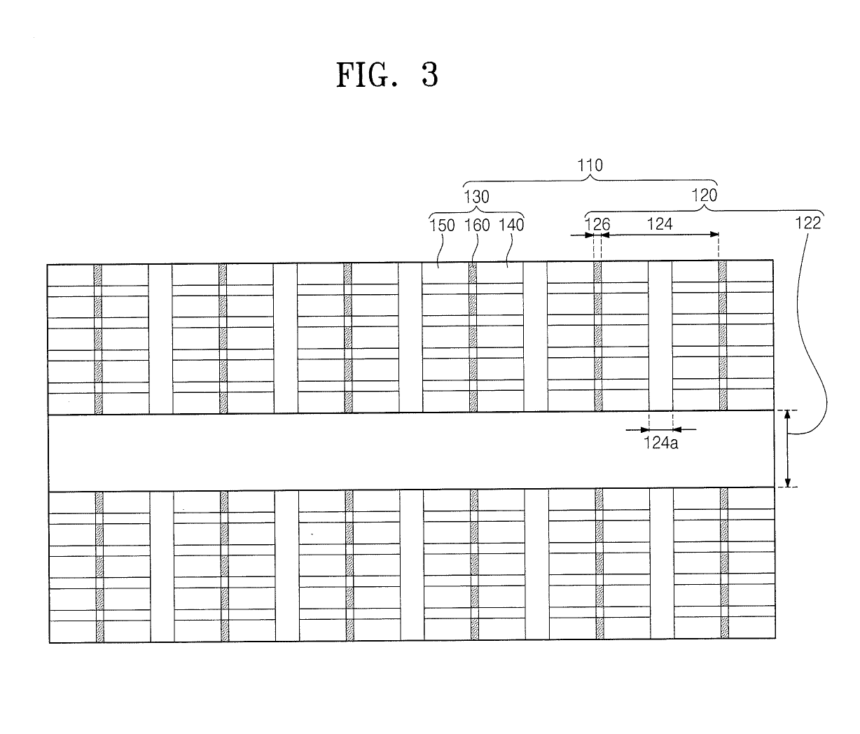

FIG. 3 illustrates a fabrication line 110 according to an example embodiment of inventive concepts.

Referring to FIG. 3, the fabrication line 110 may include load ports 160 and substrate processing apparatuses 130 including a first unit apparatus 140 and a second unit apparatus 150 at opposite sides of the load ports 160. The load ports 160 may connect between the first unit apparatus 140 and the second unit apparatus 150.

Each of operating regions 126 of a clean room 120 may have substantially the same width as that of each of the load ports 160. The plurality of load ports 160 may be disposed in one operating region 126. Each of service regions 124 may be disposed between the operating regions 126. The first unit apparatus 140 and the second unit apparatus 150 may be disposed within one service region 124. In an example, a distance between the first unit apparatus 140 and the second unit apparatus 150 within each of the service regions 124 may be greater than the width of the operating regions 126. A main passage 122 may extend in a direction crossing the service regions 124 and the operating region 126. The main passage 122 may extend from one end to the other end along a center of the clean room 120.

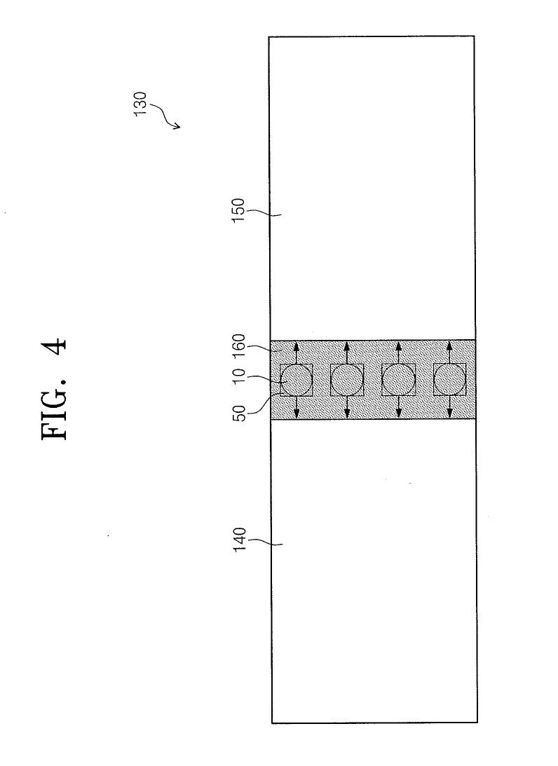

FIG. 4 illustrates one of substrate processing apparatuses 130 of FIG. 3.

Referring to FIGS. 3 and 4 again, the substrate 10 may be provided to the first unit apparatus 140 and the second unit apparatus 150 through the load ports 160. The first unit apparatus 140 and the second unit apparatus 150 may be arranged in a mirror configuration to face each other. The load ports 160 may be shared by the first unit apparatus 140 and the second unit apparatus 150. The shared load ports 160 may minimize the area of the operating regions 126.

A carrier 50 may be provided on the load port 160. The carrier 50 may receive the substrate 10. The substrate 10 may be taken in to the first unit apparatus 140 and the second unit apparatus 150. When a unit process is completed, the substrate 10 may be returned into the carrier 50.

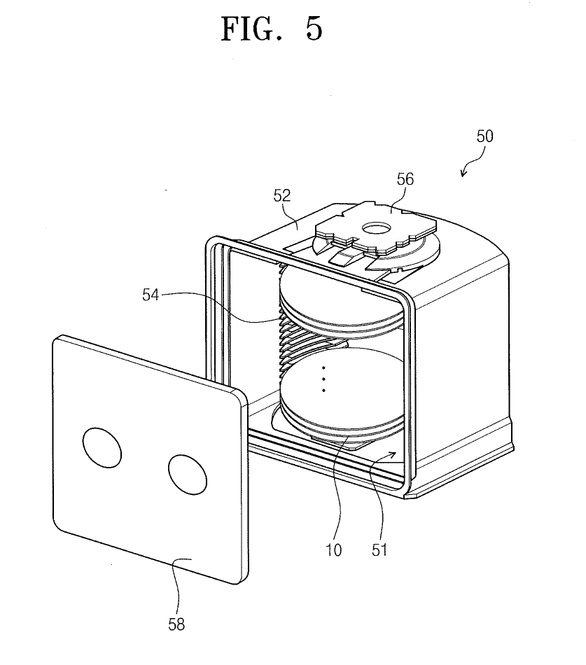

FIG. 5 is a perspective view illustrating the carrier 50 of FIG. 4.

Referring FIG. 5, the carrier 50 may be a front open unified pod (FOUP). According to an example embodiment of inventive concept, the carrier 50 may include a housing 52, slots 54, a hanger 56, and a cover 58. The housing 52 may hold the substrate 10. The housing 52 may have an entrance 51. The substrate 10 may be provided within the housing 52 through the entrance 51. The slots 54 may be disposed on an inner wall of the housing 52. The substrate 10 may be provided in the slots 54. The hanger 56 may be disposed on the housing 52. The cover 58 may be coupled to the entrance 51. The housing 52 and the cover 58 can protect the substrate 10 from a particle.

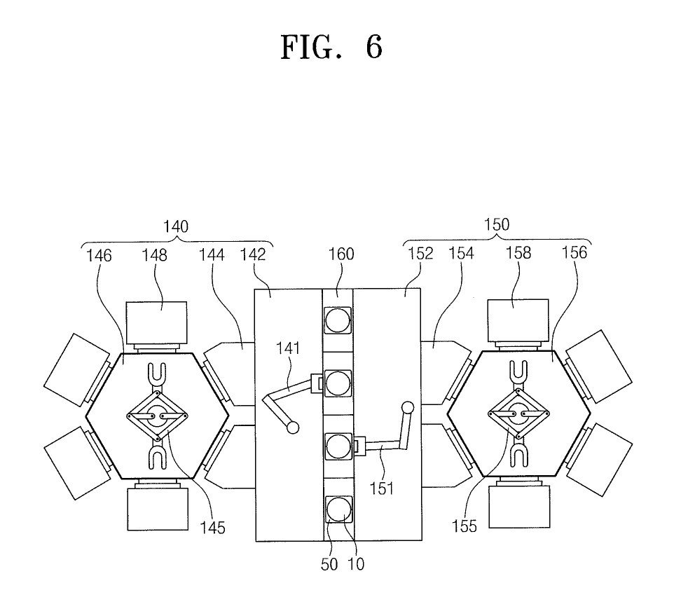

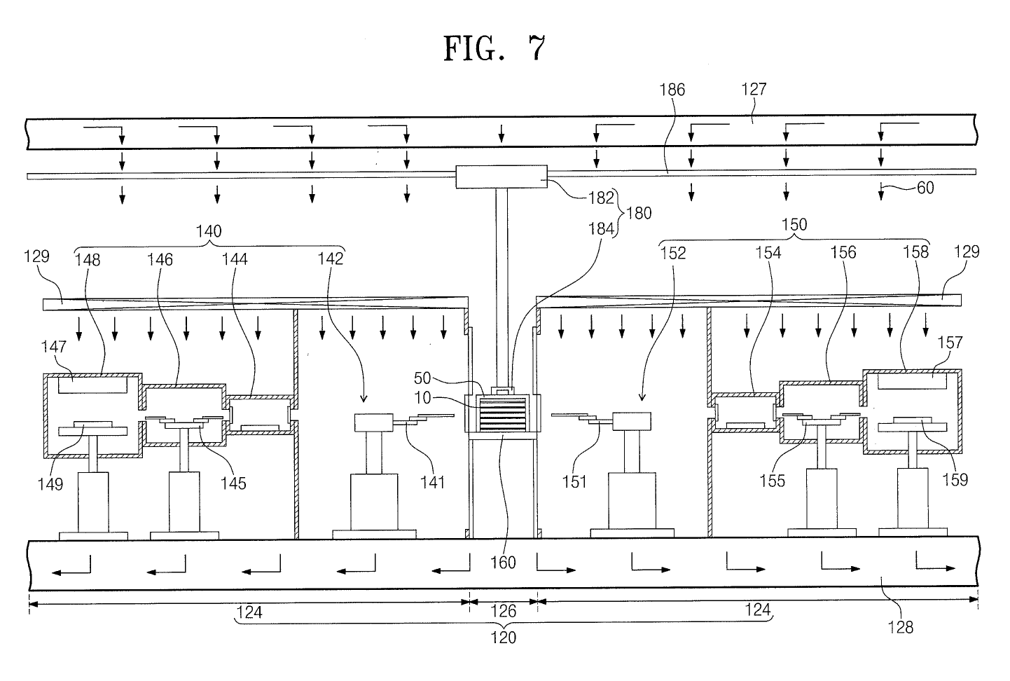

FIGS. 6 and 7 are plan and front views illustrating an example of the substrate processing apparatus 130 of FIG. 4, respectively.

Referring to FIGS. 6 and 7, the first unit apparatus 140 may include a first equipment front-end module (EFEM) 142, first load lock chambers 144, a first transfer chamber 146, and first process chambers 148. The second unit apparatus 150 may include a second EFEM and 152, second load lock chambers 154, a second transfer chamber 156, and a second process chamber 158.

The first and second EFEMs 142 and 152 may be connected to opposite sides of the load port 160. The first and second EFEMs 142 and 152 may include first and second transfer robots 141 and 151, respectively. The first and second transfer robots 141 and 151 may transfer the substrate 10 between the load lock chambers 144 and 154 and the carrier 50 of the load port 160.

The first load lock chambers 144 may be disposed between the first EFEM 142 and the first transfer chamber 146. The first load lock chambers 144 and the first transfer chamber 146 may be chambers which provide the substrate 10 to the first process chambers 148. The second load lock chambers 154 may be disposed between the second EFEM 152 and the second transfer chamber 156. The second load lock chambers 154 and the second transfer chamber 156 may be chambers which provide the substrate 10 to the second process chambers 158. The first and second load lock chambers 144 and 154, the first and second transfer chambers 146 and 156, and the first and second process chambers 148 and 158 may have substantially the same degree of vacuum.

The first transfer chamber 146 may be disposed between the first load lock chambers 144 and the first process chambers 148. The second transfer chamber 156 may be disposed between the second load lock chambers 154 and the second process chambers 158. The first and second transfer chambers 146 and 156 may have third and fourth transfer robots 145 and 155, respectively. The third transfer robot 145 may transfer the substrate 10 between the first load lock chambers 144 and the first process chambers 148. The fourth transfer robot 155 may transfer the substrate 10 between the second load lock chambers 154 and the second process chambers 158.

The first process chambers 148 may be coupled to the first transfer chamber 146 in a cluster type. The second process chambers 158 may be coupled to the second transfer chamber 156 in the cluster type. The first and second process chambers 148 and 158 of the cluster type may perform unit processes for the substrate 10, respectively. The unit process may be carried out in a single substrate manner. In some embodiments, the unit processes of the first and second process chambers 148 and 158 may be different from each other and may be performed sequentially. For example, the first process chambers 148 may include an etching apparatus. The first process chambers 148 may perform a process of etching the substrate 10. The second process chambers 158 may include a thin film deposition apparatus. The second process chambers 158 may perform a thin film deposition process.

Each of the first process chambers 148 may include a first upper electrode 147 and a first lower electrode 149. Each of the second process chambers 158 may include a second upper electrode 157 and a second lower electrode 159. Although not illustrated, the substrate 10 may be disposed on the first and second lower electrodes 149 and 159. A high-frequency power may be applied to the first upper electrode 147 and the first lower electrode 149 to induce a plasma reaction. A radio frequency (RF) power may be applied to the second upper electrode 157 and the second lower electrode 159 to induce a plasma reaction. The substrate 10 may be processed in the first and second process chambers by the plasma reaction.

In some embodiments, the first and second process chambers 148 and 158 may perform the same unit processes. Each of the first and second process chambers 148 and 158 may include an etching apparatus. In other embodiments, each of the first and second process chambers 148 and 158 may include a thin film deposition apparatus.

The first and second unit apparatus 140 and 150 and the load port 160 may be disposed on a lower plenum 128. The lower plenum 128 may exhaust air 60 through a bottom of the clean room 120. The first unit apparatus 140 and the second unit apparatus 150 may be disposed on the service region 124 and the load port 160 may be disposed on the operating region 126. An upper plenum 127 may provide filtered air 60 through a ceiling of the clean room 120. The air 60 of the operating region 126 may be managed at a class of “1000” or less. Here, the class of “1000” may be defined as 1000 particles being present in a unit volume of 1 m³.

An air filter unit 129 may be disposed on the first unit apparatus 140 and the second unit apparatus 150 within the service region 124. The air filter unit 129 may provide the filtered air 60 to the first unit apparatus 140 and the second unit apparatus 150. Air cleanliness of the service region 124 may be higher than that of the operation region 126. The air 60 of the service region 124 may be managed at a class of “100” or less. The air filter unit 129 may include a clean air supplying unit.

Referring to FIGS. 5 and 7 again, a transfer unit 180 may be moved along a rail 186. The rail 186 may be disposed under the upper plenum 127. The transfer unit 180 may transfer the carrier 50. The carrier 50 may be provided on the load port 160 by the transfer unit 180. The transfer unit 180 may include a driving unit 182 and a hoist unit 184. The hoist unit 184 may hold the hanger 56 of the carrier 50. The driving unit 182 may transfer the hoist unit 184 along the rail 186.

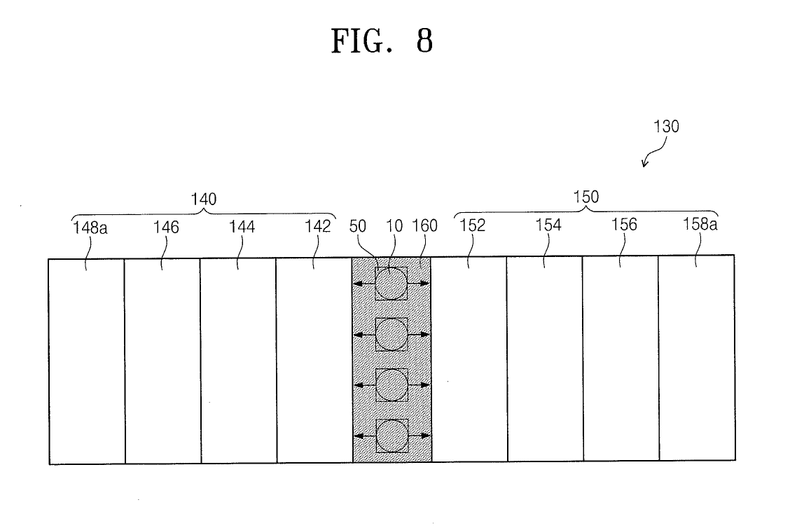

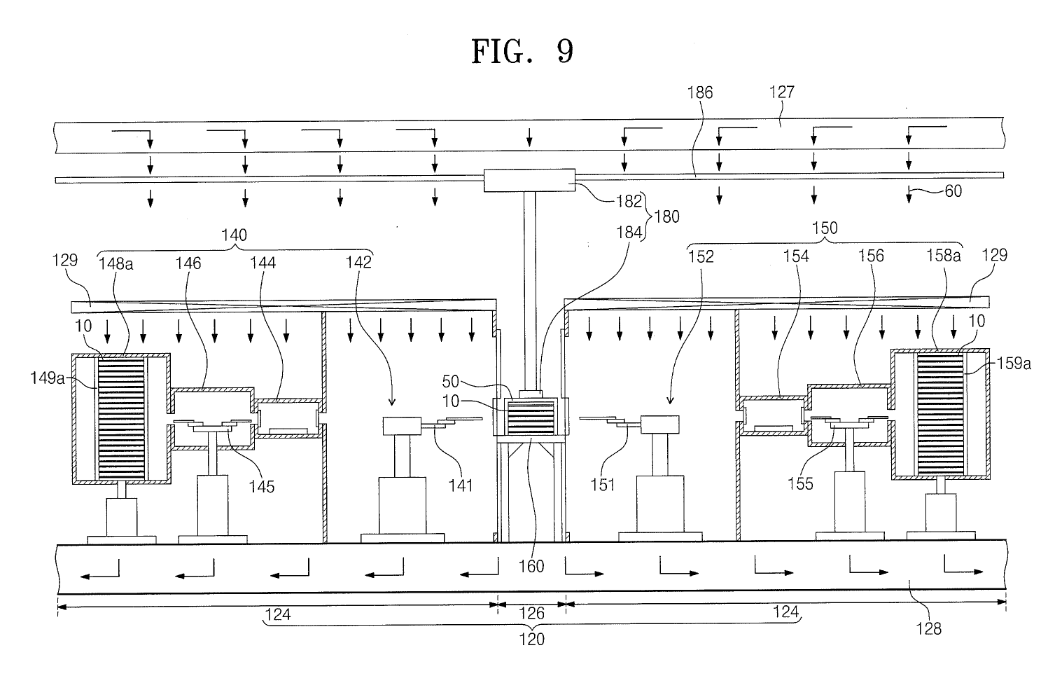

FIGS. 8 and 9 are plan and cross sectional views illustrating an example of the substrate processing apparatus 130 of FIG. 4, respectively.

Referring to FIGS. 8 and 9, the substrate processing apparatus 130 may include first and second process chambers 148a and 158a of a batch type. The first and second process chambers 148a and 158a of the batch type may perform unit processes with respect to a plurality of substrates 10. In an example, each of the first and second process chambers 148a and 158a may include a diffusion apparatus. The first and second process chambers 148a and 158a may have first and second boats 149a and 159a, respectively. The first and second boats 149a and 159a may receive hundreds of substrates 10.

An upper plenum 127, a lower plenum 128, an air filter unit 129, first and second EFEMs 142 and 152, first and second load lock chambers 144 and 154, first and second transfer chambers 146 and 156, a load port 160, and a transfer apparatus 180 of FIG. 9 may be the same as those of FIG. 7.

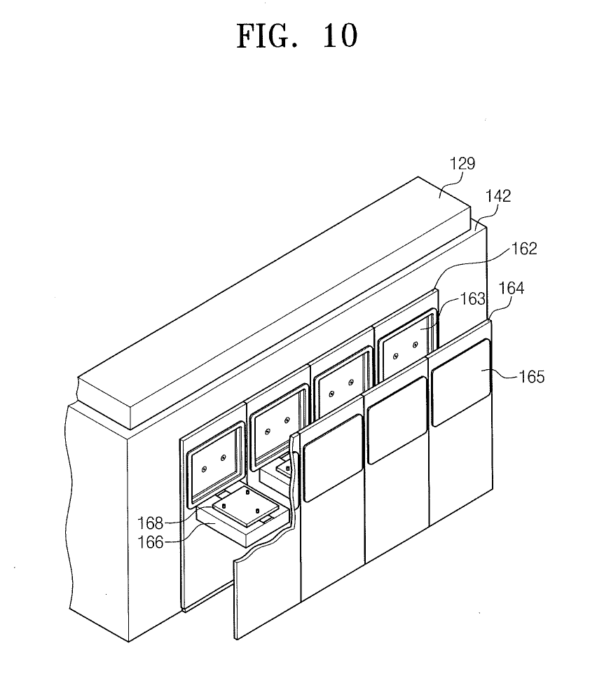

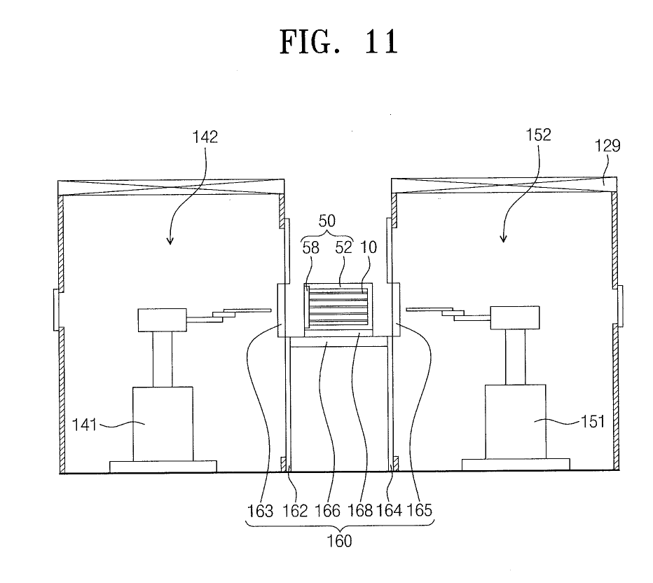

FIGS. 10 and 11 illustrate the first and second EFEMs 142 and 152 and the load port 160 of FIG. 7, respectively.

Referring to FIGS. 10 and 11, the load port 160 may be coupled to side walls of first and second EFEMs 142 and 152, respectively. The load port 160 may include first and second gate walls 162 and 164, a table 166, and a stage 168. The first gate wall 162 may be connected to the side wall of the first EFEM 142. The second gate wall 164 may be connected to the side wall of the second EFEM 152. The first and second gate walls 162 and 164 may have first and second doors 163 and 165, respectively. The table 166 may be connected to the first and second gate walls 162 and 164. The stage 168 may be disposed on the table 166. The carrier 50 may be provided on the stage 168.

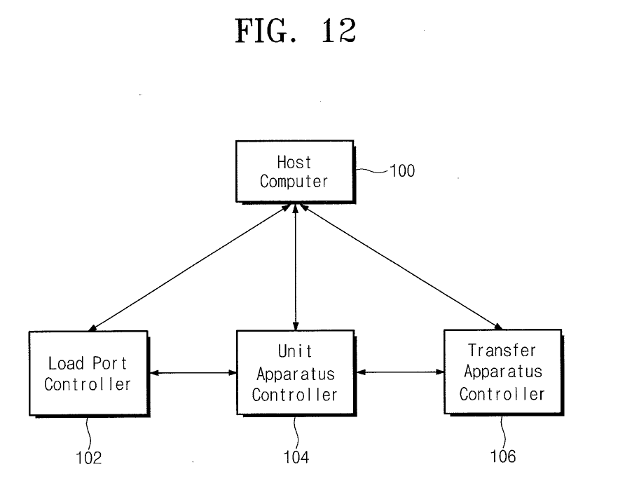

FIG. 12 illustrates a host computer 100 for controlling the fabrication line 110 of FIG. 3.

Referring to FIGS. 3, 7 and 12, a host computer 100 may manage products in the clean room 120. According to an example embodiment of inventive concepts, the host computer 100 may control the substrate processing apparatus 130 and the transfer apparatus 180. For example, the host computer 100 may communicate with a load port controller 102, a unit apparatus controller 104, and a transfer apparatus controller 106. The load port controller 102 may control the load port 160. The unit apparatus controller 104 may control the first unit apparatus 140 and the second unit apparatus 150. The transfer apparatus controller 106 may control the transfer apparatus 180. The host computer 100 may communicate with the load port controller 102, the unit apparatus controller 104 and the transfer apparatus controller 106 through TCP/IP. The load port controller 102, the unit apparatus controller 104, and the transfer apparatus controller 106 may communicate with each other through a device net.

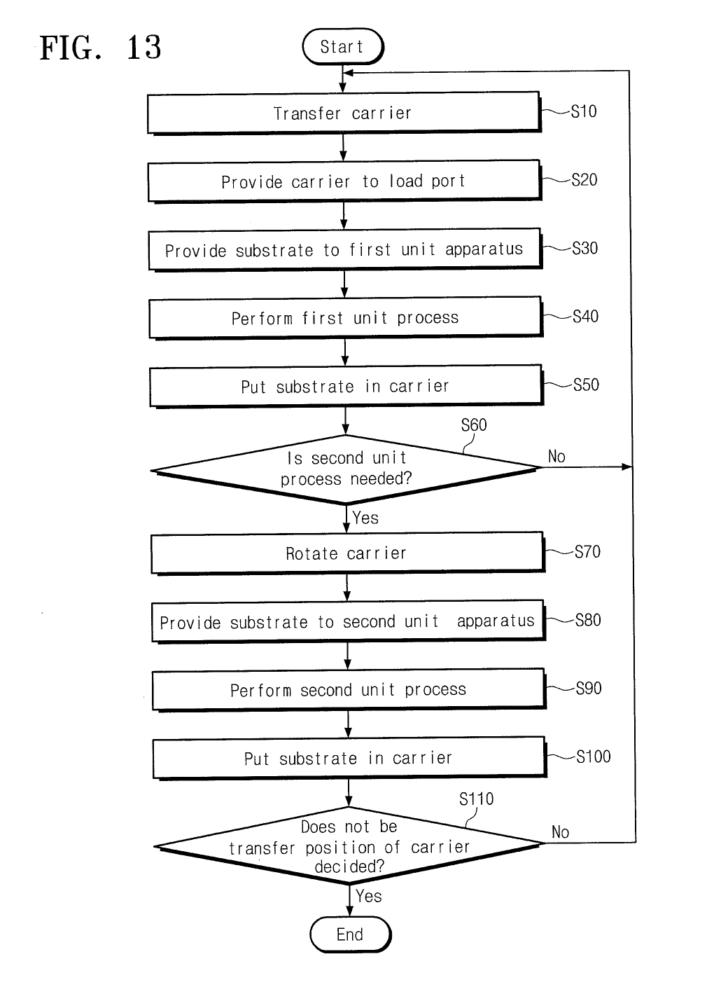

FIG. 13 is a flow chart illustrating a method for processing a substrate by the control of the host computer 100 of FIG. 12.

Referring FIGS. 3, 7 and 11 to 13, the transfer apparatus 180 may transfer the carrier 50 (S10). The carrier 50 may be transferred within the fabrication line 110. The transfer apparatus 180 may transfer the carrier 50 to the substrate processing apparatus 130.

Therefore, the transfer apparatus 180 may provide the carrier 50 to the load port 160 (S20). The carrier 50 may be provided on the stage 168. The carrier 50 may be provided on a center of the table 166.

Then, the load port 160 may provide the substrate 10 in the carrier 50 to the first unit apparatus 140 (S30).

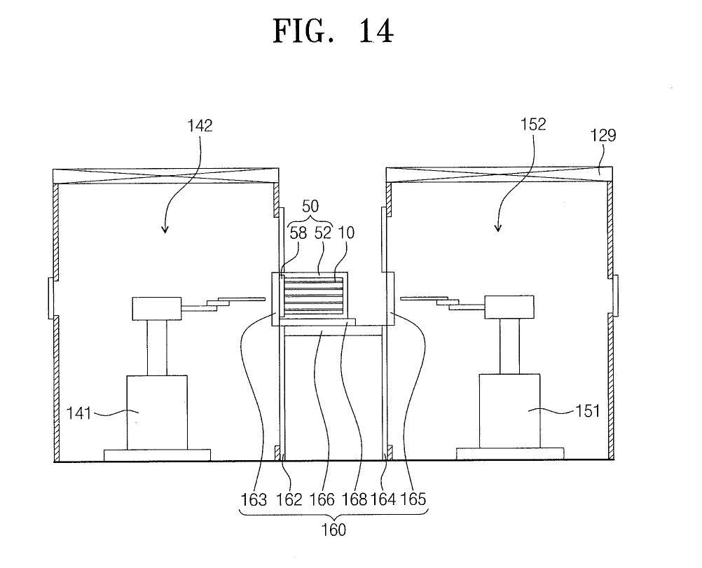

FIGS. 14 to 16 illustrate an operation of the load port 160 in the step S30 of FIG. 13 in which the substrate is provided to the first unit apparatus 140.

Referring to FIG. 14, the stage 168 may transfer the carrier 50 to a first door 163. The cover 58 of the carrier 50 may be clamped to the first door 163.

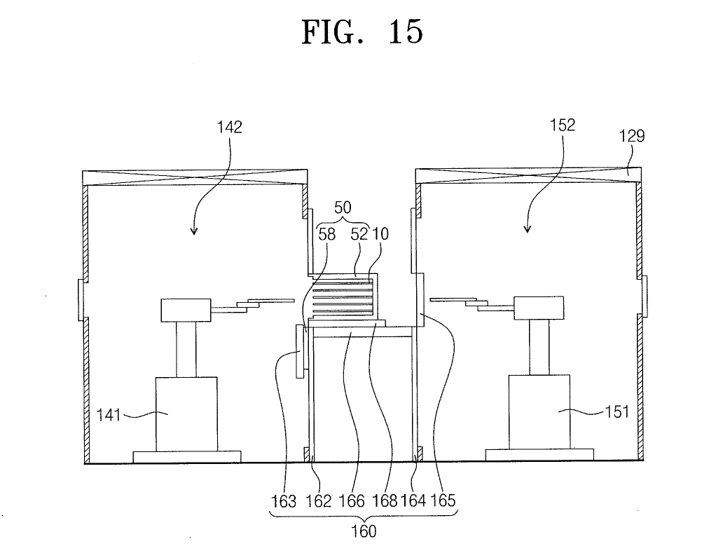

Referring to FIG. 15, the first door 163 may open the cover 58. The first door 163 and the cover 58 may move along the first gate wall 162. The first EFEM 142 and the housing 52 of the carrier 50 may be interlocked with each other.

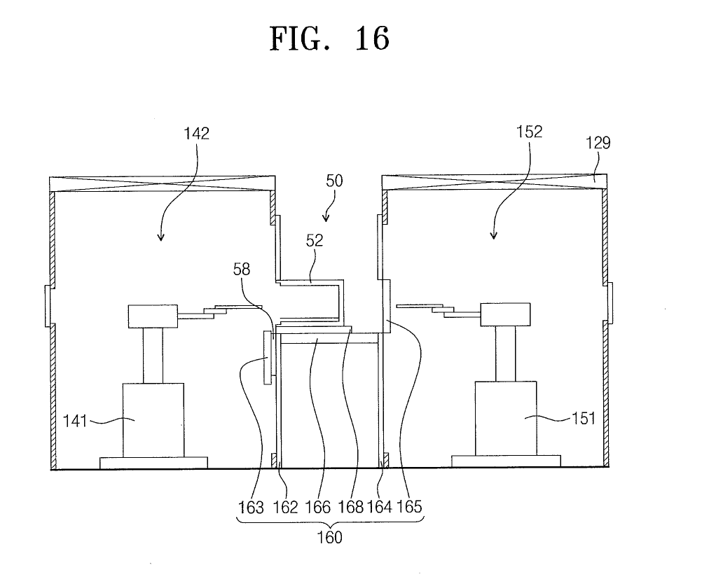

Referring to FIGS. 7 and 16, the first transfer robot 141 may take out the substrate 10 in the carrier 50. The substrate 10 may be provided into the first process chamber 148 through the first load lock chamber 144 and the first transfer chamber 146.

Referring to FIGS. 6, 7 and 13, the first process chamber 148 may perform the unit process for the substrate 10 (S40). For example, the first unit process may include a process of etching the substrate 10. When the first unit process is completed, the substrate 10 may be transferred from the first process chamber 148 to the first EFEM 142.

Referring to FIGS. 11, 13 to 15 again, the first transfer robot 141 may put the substrate 10 into the carrier 50 (S50)(see FIG. 15). The first door 163 may combine the cover 58 with the housing 52 (see FIG. 14). The first EFEM 142 and the carrier 50 may be separated. The stage 168 may transfer the carrier 50 to the center of the table 166 (see FIG. 11).

Referring to FIGS. 12 and 13, the host computer 100 may determine whether to perform a second unit process (S60). When first and second unit processes for the substrate 10 are substantially the same, the carrier 50 may be transferred to another substrate processing apparatus 130 (S10). Alternatively, when the second unit process for the substrate 10 is carried out continuously in the substrate processing apparatus 130, a direction of the carrier 50 may be changed.

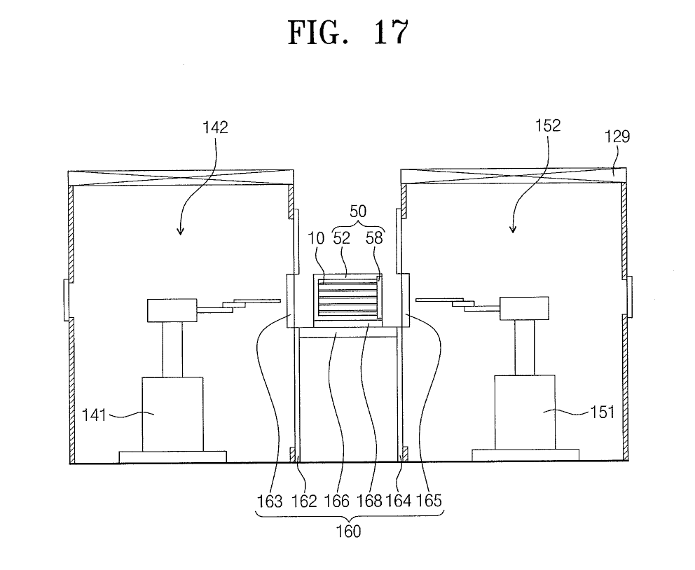

FIG. 17 illustrates the carrier 50 which is rotated in a direction of the second EFEM 152 of FIG. 11.

Referring to FIGS. 11, 13 and 17, the load port 160 may rotate the carrier 50 (S70). According to an example embodiment of inventive concept, the cover 58 (or the entrance 51) of the carrier 50 may be rotated from a direction of the first EFEM 142 to a direction of the second EFEM 152. For example, the carrier 50 may be rotated by 180°. The stage 168 and the carrier 50 may be rotated at the center of the table 166.

Next, the load port 160 may provide the substrate 10 to the second unit apparatus 150 (S80).

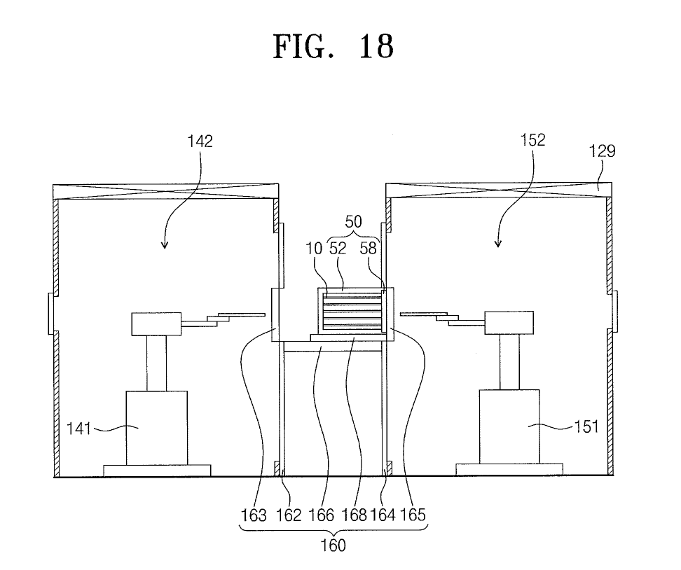

FIGS. 18 to 20 illustrate an operation of the load port 160 in the step (S50) of FIG. 13 in which the substrate is provided to the second unit apparatus.

Referring to FIG. 18, the stage 168 may transfer the carrier 50 to the second door 165. The cover 58 may be clamped with the second door 165.

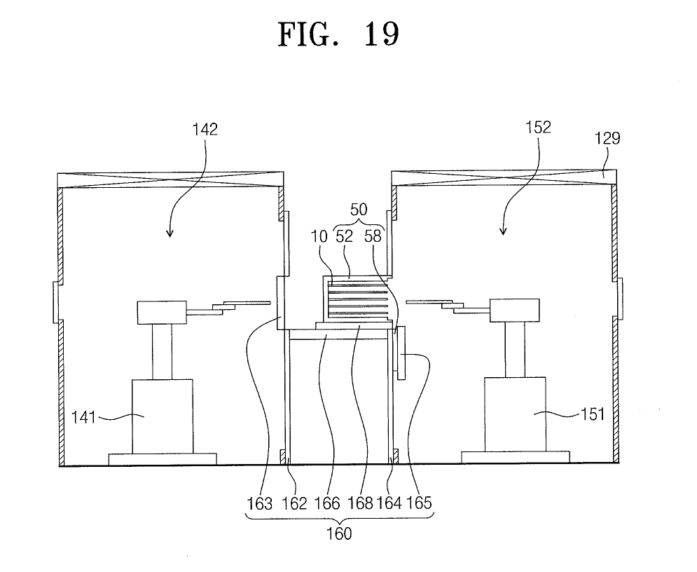

Referring to FIG. 19, the second door 165 may open the cover 58. The second door 165 and the cover 58 may be moved along the second gate wall 164. The second EFEM 152 and the housing 52 may be interlocked with each other.

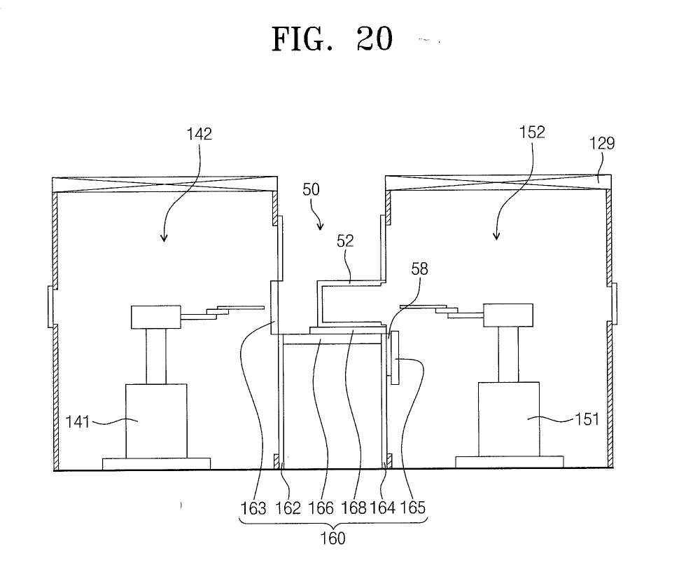

Referring to FIGS. 7 and 20, the second transfer robot 151 may take out the substrate 10 in the carrier 50. The substrate 10 may be provided into the second process chamber 158 through the second load lock chamber 154 and the second transfer chamber 156.

Referring to FIGS. 6, 7 and 13, the second process chamber 158 may perform the second unit process for the substrate 10 (S90). The second unit process may include a thin film deposition process. When the second unit process is completed, the substrate 10 may be transferred from the second process chamber 158 to the second EFEM 152.

Referring to FIGS. 11, 13 and 18 to 19 again, the second transfer robot 151 may put the substrate 10 in the carrier 50 again (S100). When the second unit process is completed, the second transfer robot 151 may put the substrate 10 in the carrier 50. The second door 165 may allow the cover 58 to be clamped with the housing 52. The second EFEM 152 and the carrier 50 may be separated. The stage 168 may transfer the carrier 50 to the center of the table 166.

Next, the host computer 100 may determine a transfer position of the carrier 50 (S110). When the transfer position is determined, the transfer unit 180 may transfer the carrier 50 (S10).

As described above, according to example embodiments of the inventive concept, the first unit apparatus and the second unit apparatus of the substrate processing apparatus may share the load port. The shared load port may minimize an operating region, thereby improving space efficiency of the semiconductor fabrication line.

While the inventive concepts has been described with reference to exemplary embodiments, it will be apparent to those skilled in the art that various changes and modifications may be made without departing from the spirit and scope of the inventive concepts. Therefore, it should be understood that the above embodiments are not limiting, but illustrative.

What is claimed is:

1. An apparatus for processing a substrate, the apparatus comprising:
a first unit apparatus performing a first unit process for the substrate;
a second unit apparatus facing the first unit apparatus, the second unit apparatus performing a second unit process for the substrate; and
a load port providing a carrier receiving the substrate to the first unit apparatus and the second unit apparatus, the load port connecting between the first unit apparatus and the second unit apparatus and between the first unit apparatus and the second unit process.

2. The apparatus of claim 1, wherein the load port comprises:
a first gate wall connected to the first unit apparatus;
a second gate wall connected to the second unit apparatus; and
a table connecting between the first gate wall and the second gate wall.

3. The apparatus of claim 2, wherein the load port further comprises:
a stage on the table, the stage transferring the carrier to the first gate wall and the second gate wall.

4. The apparatus of claim 3, wherein the first and second gate walls comprise first and second doors, respectively, and
wherein, when the stage is moved to the first and second gate walls, one of the first and second doors is opened and the other is closed.

5. The apparatus of claim 3, wherein the stage rotates an entrance of the carrier from a direction toward one of the first and second gate walls to a direction toward the other.

6. The apparatus of claim 5, wherein the stage rotates the carrier by 180°.

7. The apparatus of claim 5, wherein the stage rotates at a center of the table.

8. The apparatus of claim 2, wherein the first unit apparatus further comprise:
a first EFEM coupled to the first gate wall;
a first load lock chamber connected to the first EFEM;
a first transfer chamber connected to the first load lock chamber; and
first process chambers connected to the first transfer chamber in a cluster type, and
wherein the second unit apparatus further comprise:
a second EFEM coupled to the second gate wall;
a second load lock chamber connected to the second EFEM;
a second transfer chamber connected to the second load lock chamber; and
second process chambers connected to the second transfer chamber in a cluster type.

9. The apparatus of claim 8, wherein the first and second process chambers comprise an etching apparatus and a thin film deposition apparatus, respectively.

10. A fabrication line comprising:
a clean room; and
a substrate processing apparatus provided in the clean room, the substrate processing apparatus performing a substrate manufacturing process,
wherein the substrate processing apparatus comprises:
a first unit apparatus performing a first unit process for a substrate;
a second unit apparatus facing the first unit apparatus, a second unit apparatus performing a second unit process for the substrate; and
a load port providing a carrier receiving the substrate to the first unit apparatus and the second unit apparatus, the load port connecting between the first unit apparatus and the second unit apparatus and between the first unit apparatus and the second unit apparatus.

11. The fabrication line of claim 10, wherein the clean room comprises:
service regions in which the first unit apparatus and the second unit apparatus are disposed; and
an operating region in which the load port is between the service regions, and
wherein a width of the operating region is less than a distance between the first unit apparatus and the second unit apparatus within each of the service regions.

12. The fabrication line of claim 11, wherein the width of each of the operating regions is substantially equal to a width of the load port.

13. The fabrication line of claim 10, wherein the load port comprises:
a first gate wall connected to the first unit apparatus;
a second gate wall connected to the second unit apparatus;
a table connecting between the first and second gate walls; and
a stage on the table, the stage transferring the carrier between the first and second gate walls.

14. The fabrication line of claim 13, wherein the stage rotates an entrance of the carrier from a direction of the first gate wall to a direction of the second gate wall.

15. The fabrication line of claim 14, further comprising:
a transfer apparatus in the clean room, the transfer apparatus providing the carrier on the stage.

16. A method for processing a substrate, the method comprising:
providing a carrier receiving the substrate to a load port;
providing the substrate from the carrier to a first unit apparatus to perform a first unit process on the substrate;
putting the substrate in the carrier after performing the first unit process;
rotating the carrier from a direction of the first unit apparatus to a direction of a second unit apparatus facing the first unit apparatus; and
providing the substrate from the carrier to the second unit apparatus to perform a second unit process on the substrate.

17. The method of claim 16, wherein the first and second unit processes are an etching process and a thin film deposition process, respectively.

18. The method of claim 16, wherein the load port comprises:
a first gate wall connected to the first unit apparatus;
a second gate wall connected to the second unit apparatus;
a table connecting between the first gate wall and the second gate wall; and
a stage on the table to support the carrier, and
wherein rotating of the carrier comprises rotating an entrance of the carrier from a direction of the first gate wall to a direction of the second gate wall.

19. The method of claim 18, wherein providing the substrate to the first unit apparatus comprises:
transferring the carrier from a center of the table to the first gate wall; and
opening a cover of the carrier and a first door of the first gate wall.

20. The method of claim 18, wherein the carrier is rotated on a center of the table by the stage, and
wherein providing the substrate to the second unit apparatus comprises:
transferring the carrier from the center of the table to the second gate wall; and
opening a cover of the carrier and a second door of the second gate wall.
